(19) United States
(12) Patent Application Publication
(10) Pub. No.: US 2007/0287210 A1
(43) Pub. Date: Dec. 13, 2007

(54) Method for assembling a semiconductor laser module

(76) Inventor: Toshiaki Kihara, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/806,264

(22) Filed: May 30, 2007

(30) Foreign Application Priority Data
Jun. 1, 2006 (JP) 2006-153762

(51) Int. Cl. H01L 21/00

(52) U.S. Cl. 438/26; 257/E21.002

(57) ABSTRACT

A method and an apparatus for assembling a semiconductor laser module to prevent excess solder from scattering without saving an amount of the solder is disclosed. The method has a feature that, after heating up the die-bonder and holding the temperature of the die-bonder in a preset period, the excess solder may be sucked with the nozzle by scanning the nozzle along the gap between the carrier and the TEC. Because the whole boundary is scanned, the excess solder may be sucked even if the solder oozes out any portion on the boundary.

### BACKGROUND OF THE INVENTION

1. Field of the Invention

The present invention relates to a method for assembling a semiconductor laser module and relates to an apparatus for assembling the same.

2. Related Prior Art

The Japanese Patent published as JP-H05-067844A has disclosed a type of a semiconductor laser module that includes a carrier for mounting the semiconductor laser diode, a thermo-electric cooler (TEC) fixed to a bottom surface of the carrier with solder to dissipate heat generated by the laser diode through the carrier, and a package that installs the carrier and the TEC. In such conventional module, because the laser diode is heated up or cooled down by the TEC through the carrier, the bottom surface of the carrier and the top plate of the TEC are preferable to have a same configuration, namely, to have the same shape and the same area. In such laser module, the carrier is fixed to the TEC by melting the solder interposed between the carrier and the TEC after setting the carrier on the TEC.

However, when the carrier in the bottom surface thereof and the TEC in the top plate have the same shape and the area, the excess solder oozes out the boundary therebetween and turns into a solid ball by the surface tension, which may scatter or fly off to cause damage to the laser diode or to the interconnection to the laser diode within the package. Accordingly, a conventional method to assemble the module often saves an amount of the solder interposed between the carrier and the TEC to suppress the excess solder from oozing out, which may degrade the bond strength and the heat-dissipating efficiency of the laser diode.

Therefore, the present invention is to provide a method and an apparatus for assembling the semiconductor laser module that prevents the excess solder between the carrier and the TEC from scattering.

### SUMMARY OF THE INVENTION

According to the present invention, a method for assembling a semiconductor laser module is provided. The laser module includes a carrier, a thermo-electric cooler (TEC) and a package that installs the carrier and the TEC therein. The carrier mounts a semiconductor laser thereon. The TEC, which is comprised of an upper plate, a lower plate and a plurality of Peltier elements between these upper and lower plates, fixes the carrier on the upper plate to heat up or to cool down a temperature of the laser diode. The method according to the present invention has features of (a) preparing a nozzle with a sucking port in a tip portion thereof, (b) positioning the carrier on the TEC with solder interposed between the carrier and the upper plate of the thermo-electric cooler, (c) melting the solder between the carrier and the TEC, and (d) scanning the nozzle so as to run the sucking port thereof along the gap between the carrier and the TEC to suck excess solder oozed out the gap.

According to the method, enough solder is provided between the carrier and the TEC fixes the carrier as the carrier is pressed against the carrier, which not only enhances the positional accuracy of the carrier on the TEC but also maintains the adhesive strength by the solder. Then, the excess solder oozed out the gap between the carrier and the TEC may be sucked by the nozzle running along the gap, which reliably sucks the oozed solder in any portion of the gap and prevents the solder from scattering. Thus, according to the present invention, the excess solder may be thoroughly collected by the vacuum nozzle without cutting an amount of the solder.

### BRIEF DESCRIPTION OF DRAWINGS

FIG. 1 is a perspective view showing a semiconductor laser module manufactured by a method and an apparatus according to an embodiment of the present invention;

FIG. 2 shows an inside of the laser module illustrated in FIG. 1;

FIG. 3 is a plan view schematically showing an apparatus according to the present embodiment;

FIG. 4 is a side view of the apparatus illustrated in FIG. 3;

FIG. 5A magnifies a tip portion of the nozzle provided in the apparatus, FIG. 5B is a side view of the tip portion and FIG. 5C is a front view of the nozzle;

FIG. 6 illustrates a process to suck excess solder by the nozzle shown in FIGS. from 5A to 5C;

FIG. 7 shows a process to set a thermo-electric cooler (TEC) on the die-bonder;

FIG. 8 shows a process to set a carrier on the TEC with solder between the carrier and the TEC;

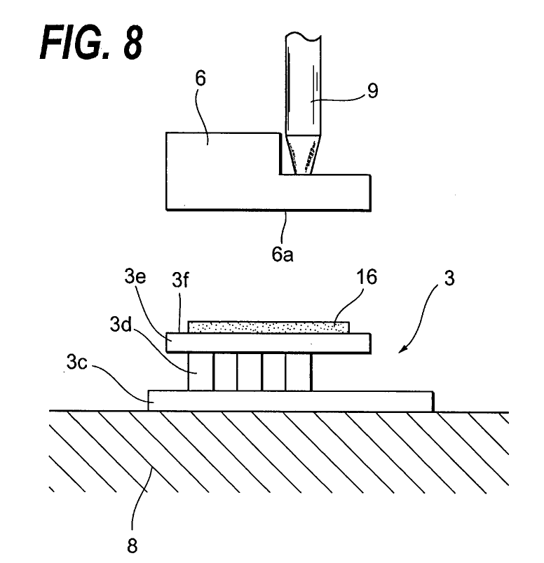

FIG. 9 illustrates a condition where excess solder oozes out the gap between the carrier and the TEC;

FIG. 10 schematically shows a process to remove excess solder by nozzles;

FIG. 11 schematically shows a position of the tip of the nozzle with respect to the TEC and the carrier;

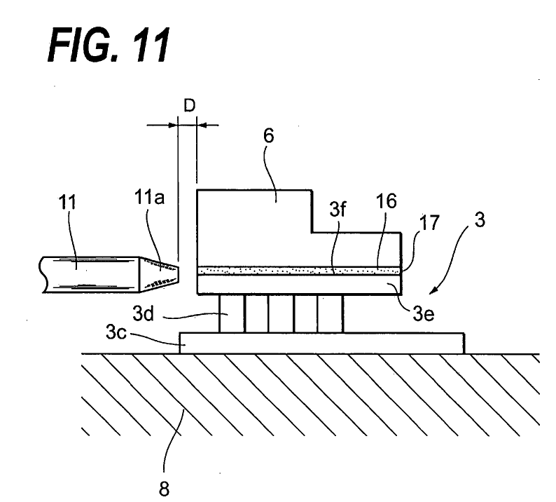

FIG. 12 shows temperature profiles of the die-bonder and the top of the TEC;

FIG. 13 shows a process to set the TEC with the carrier within the package; and

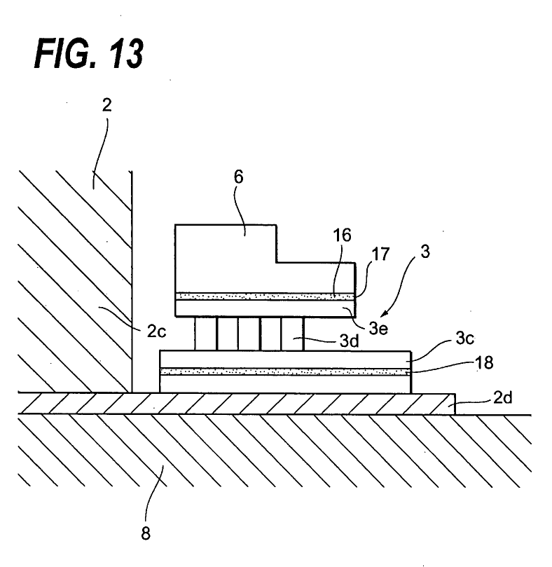

FIG. 14A is a side view showing a modified nozzle and FIG. 14B illustrates a process where the modified nozzle sucks the excess solder.

### DESCRIPTION OF PREFERRED EMBODIMENTS

Next, a method for assembling a semiconductor laser module and an apparatus for manufacturing the laser module according to the present invention will be described as referring to accompanying drawings.

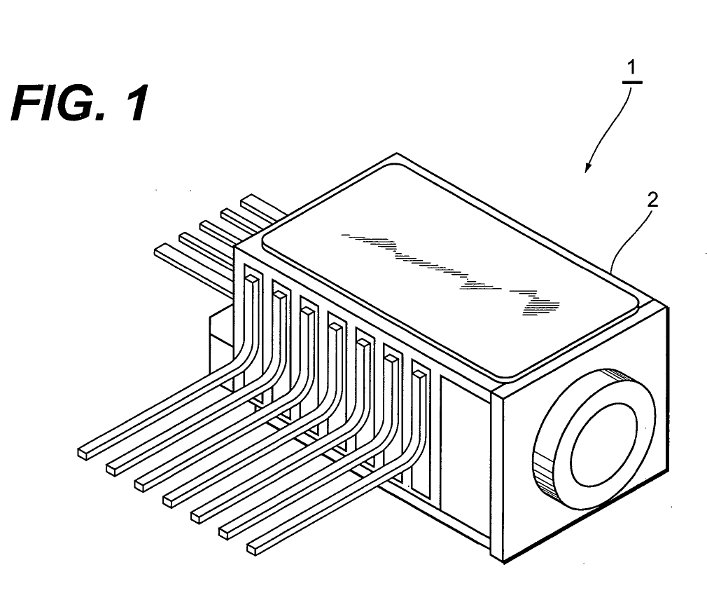

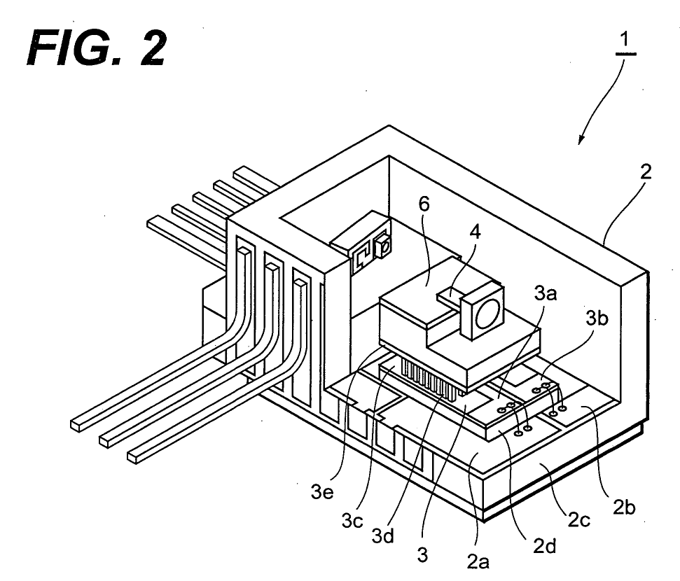

FIG. 1 is a perspective view showing a semiconductor laser module according to the present invention, and FIG. 2 is a partially broken view of the laser module to show an inner arrangement thereof. The semiconductor laser module 1 obtained by a method of the present invention, as shown in FIGS. 1 and 2, provides a box-shaped package 2 within which a thermo-electric cooler (hereinafter denoted as TEC) with electrodes, 3a and 3b, is installed. On the TEC is mounted with a carrier 6, and a semiconductor device 4 is mounted on this carrier 6.

The package 2 provides a portion 2c that stacks a plurality of ceramics. On the portion 2c is provided with two electrodes, 2a and 2b, electrically connected with electrodes, 3a and 3b, of the TEC. The package 2 also provides a substrate 2d for mounting the TEC 3 thereon with solder. The carrier 6 on the TEC is fixed to the TEC 3 with solder.

The TEC 3 comprises a bottom plate 3c, a plurality of Peltier elements 3d and an upper plate 3e. Each Peltier element includes p-type and n-type semiconductor with a pn-junction. The semiconductor device 4 mounted on the upper plate 3e through the carrier 6 may be heated up or cooled down by flowing a current in the Peltier elements. The condition whether the upper plate is heated up or cooled down depends on the direction of this current. When an ambient temperature of the semiconductor device 4 is higher than a preset temperature, the TEC 3 cools down the upper plate 3e, while, heats up the lower plate 3c and dissipates the heat from the lower plate 3c to the outside of the package 2, which may cool down the carrier 6 and the semiconductor device 4. Oppositely, when an ambient temperature of the device 4 is lower than a preset condition, the upper plate 3d is heated up, while, the lower plate is cooled down, which raises the temperature of the device 4 with the carrier 6. In order to effectively heat up or cool down the temperature of the device 4, it is preferable to size the carrier 6 to the upper plate 3e.

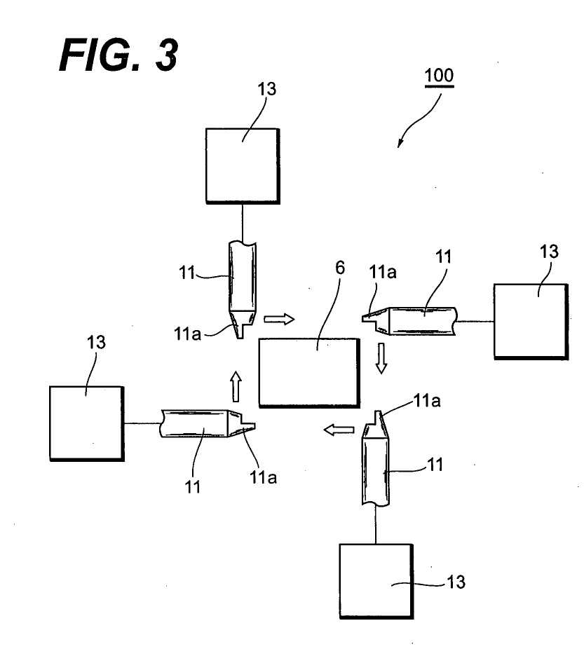

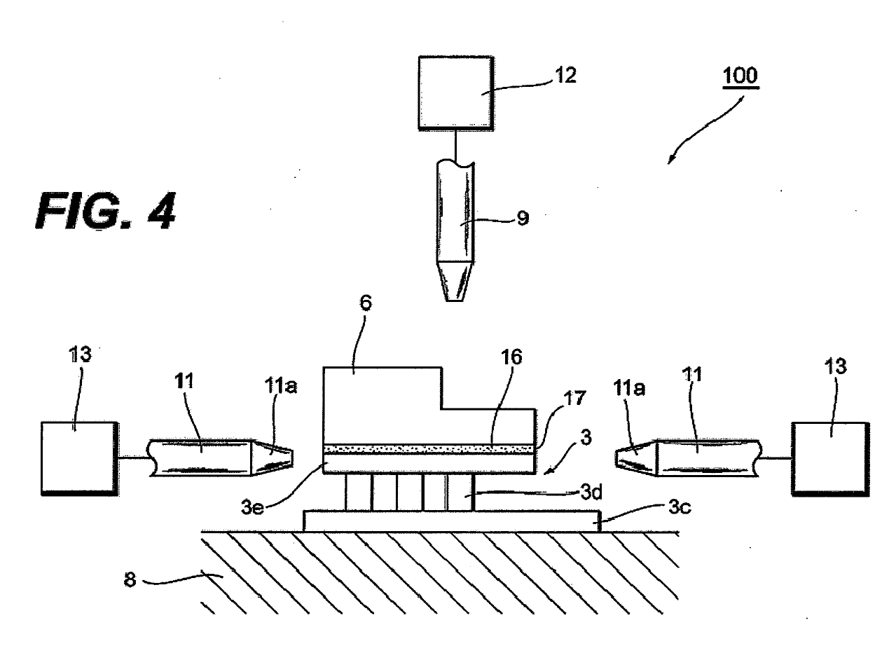

An apparatus 100 to assembly the laser module 1 provides a die-bonder 8 that heats up the solder between the carrier and the upper plate 3e of the TEC 3, a collet 9 configured to stick the carrier 6 and to position the carrier with respect to the TEC 3, and four nozzles 11 to suck the excess solder oozed from the boundary 17 between the carrier 6 and the TEC 3, as shown in FIGS. 3 and 4. Each nozzle 11 levels off with respect to the die-bonder 8 and a tip 11a thereof heads for every side of the TEC 3 and the carrier 6.

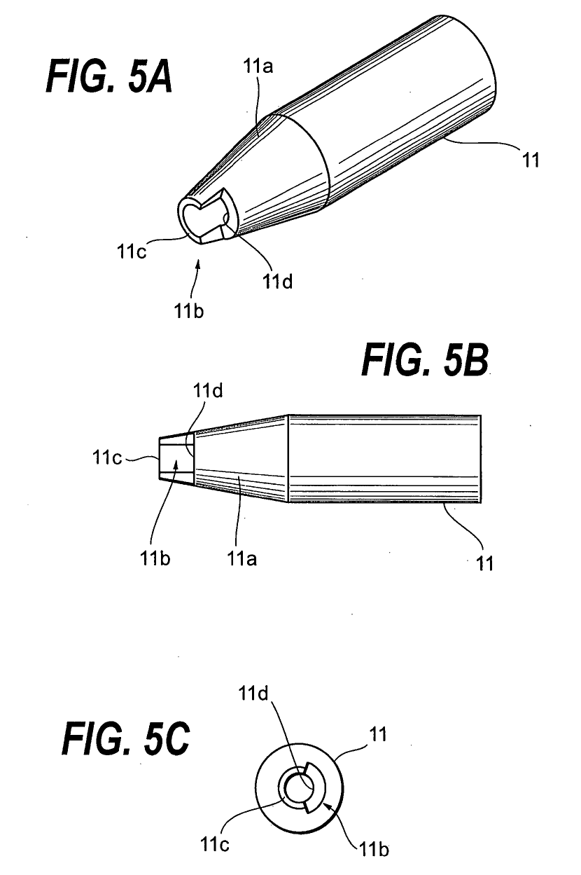

FIGS. 5A to 5C illustrate a detail of the nozzle 11. The nozzle 11 proves a through hole 11d to such the solder. The tip 11a of the nozzle 11 is partially cut to form portions, 11b and 11c, to suck the solder from the side of the nozzle 11 by the former portion 11b, while, the latter portion 11c receives the sucked solder.

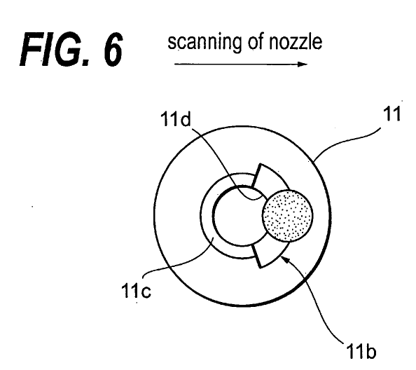

Sliding the nozzle 11 as the portion 11b faces the solder, as shown in FIG. 6, the solder comes in the portion 11b and is sucked within the through hole 11d. The other portion 11c of the tip of the nozzle 11 receives the solder not sucked within the through hole 11d, and may be gradually absorbed in the through hole 11d. Thus, the cut in the tip of the nozzle 11 that forms two portions, 11c and 11d, may reliably suck the excess solder.

The driver 12 may slide the collet 9 in three axes, and other drivers 13 may move each nozzle 11 in three axes. The driver 12 includes a motor to drive the collet 9 and mechanisms to guide the collet 9. The other drivers 13 each includes a motor to drive the collet 9 and mechanisms to guide each nozzle 11. The apparatus 100 may be preferable to keep the mechanism explained above within an inactive atmosphere, such as a nitrogen ambient atmosphere, to prevent the solder from oxidizing.

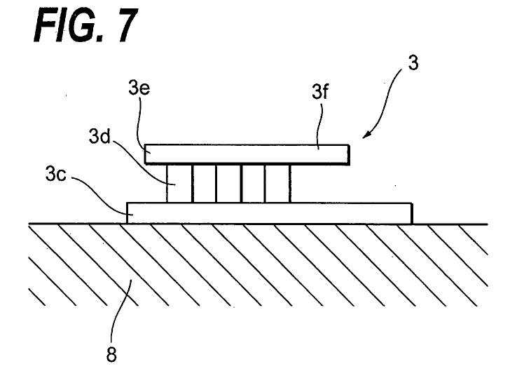

Next, a method for manufacturing the semiconductor laser module 1 explained above will be described. First, as shown in FIG. 7, the apparatus 100 sets the TEC 3 on the die-bonder 8. Providing the solder 16 on the surface 3f of the upper plate 3e and positioning the carrier 6 with respect to the TEC 3 by suctioning the carrier 6 with the collet 9, the carrier 6 is set on the upper plate 3e. Even after setting the carrier 6, the carrier 6 is pressed against the TEC 3 not to slide the carrier 6 when the solder is melted. As pressing the carrier 6 by the collet 11, the solder 16 is melted by heating up the die-bonder to increase the temperature of the TEC 3 and the carrier 6.

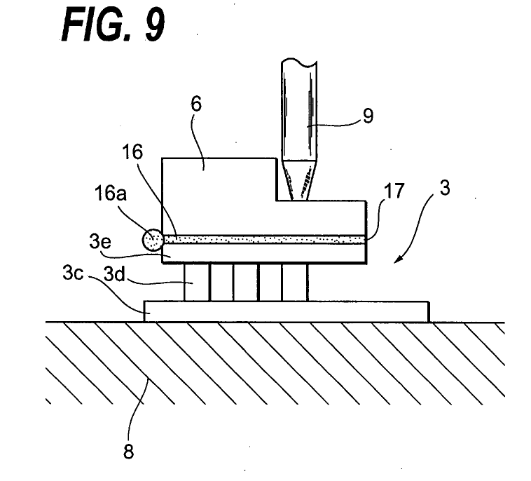

The melted solder 16, as shown in FIG. 9, often oozes out the gap 17 between the carrier 6 and the upper plate 3e. Because the area of the carrier 6 and that of the upper plate 3e are nearly equal to each other, the oozed solder 16 accumulates at the gap 17 as forming a solder ball 16a by the surface tension. The size of the solder ball 16a depends on an amount of the original solder provided on the upper plate 3e of the TEC and the force for pressing the carrier against the upper plate 3e by the collet 9. Typical diameters thereof are smaller than 1 mm.

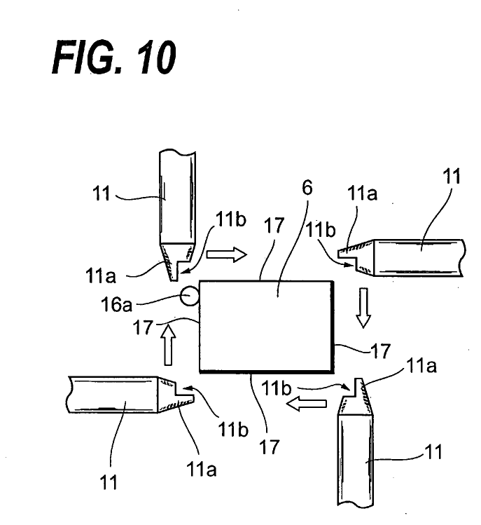

FIG. 10 schematically illustrates an arrangement of four nozzles 11 with respect to the module 1, in which the nozzles position in respective corner of the carrier 6 as facing the tip portion 11b thereof to the carrier 6. The driver 13 of the nozzle 11 adjusts the gap D between the tip 11b of the nozzle and the gap 17 to be, for example, 0.05 mm to 0.1 mm. Heating up the die-bonder 8 and after the excess solder 16a oozes out the gap 17, scanning each nozzle 11 along the gap 17 to the other corner of the carrier 6, the excess solder 16a may be sucked by the nozzle 11.

Thus, between the TEC 3 and the carrier 6 is scanned in a whole periphery with the nozzle 11, which completely sucks the excess solder 16a even when the solder oozes out anywhere in the gap 17 between the carrier 6 and the TEC 3. The collet 9 always presses the carrier 6 against the TEC 3 during the sucking of the solder 16, which prevents the carrier from slipping. To keep the pressure against the TEC 3 constant may prevent the excess solder 16 from oozing out the gap 17 again after once sucking by the nozzle 11.

Finishing the sucking of the excess solder 16a with the nozzle 11, the apparatus 100 cools down the temperature of the die-bonder 8 to solidify the solder 16, which fixes the carrier 6 to the TEC 3. Thus, the process described above prevents the excess solder 16a from scattering without reducing an amount of the solder placed on the upper plate 3e of the TEC 3. Moreover, the process above carries the fixing of the carrier 6 to the TEC 3 outside the package 2, which enables to use a small sized package for the optical module where an enough room is unable to be provided for scanning the nozzle 11.

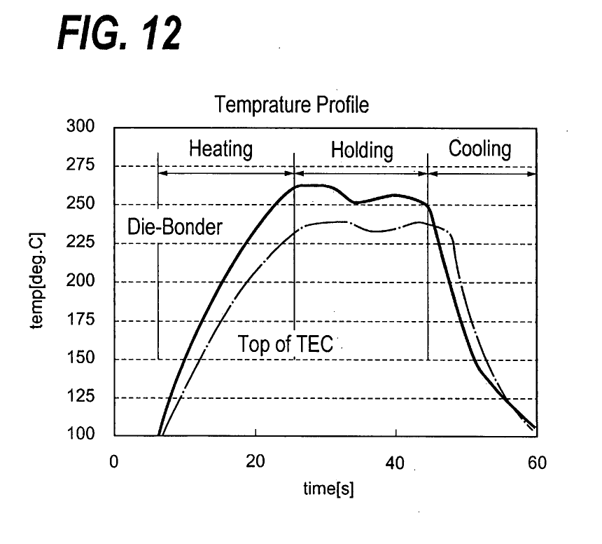

In advance to the practical process for melting the solder 16, it is preferable to provide various process parameters, such as a period from the begging of the heating up of the die-bonder 8 to a time when the temperature thereof becomes a melting point of the solder 16, a period during which the die-bonder is held in its temperature to melt the solder 16, and a period required to solidify the solder 16, and to prepare a temperature profile illustrate in FIG. 12. Because of the oxidization of the solder when it is set in an atmosphere higher than the melting temperature, it is preferable that to hold the temperature of the die-bonder 8 in the melting temperature is from 10 seconds to 30 seconds taking a process to remove the excess solder by the nozzle 11 into account.

Setting the timing to scan the collet 9 and the nozzle 11, and the sequence to heat up or to cool down the die-bonder 8 based on the profile thus prepared, the apparatus 100 automatically processes the works to be carried out. The workability and the productivity of the module may enhance compared to a conventional method where the excess solder is removed with, for example, tweezers.

After fixing the carrier 6 to the TEC 3, the process sets the package 2 on the die-bonder 8, and places the TEC 3 assembled with the carrier 6 on the plate 2d of the package 2. Heating up the die-bonder 8 again to melt the solder 18 between the plate 2d and the bottom plate 3c of the TEC and cooling down to solidify the solder, the TEC 3 with the carrier 6 may be fixed to the package 2. The solder 13 is preferable to have a melting point thereof lower than that of the solder 17 between the carrier 6 and the TEC 3.

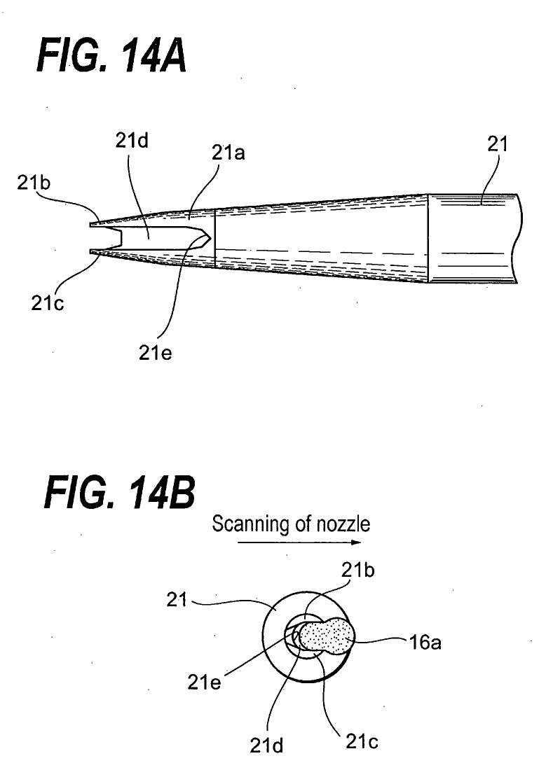

The present invention may be not restricted to those embodiments described hereinabove. For instance, the nozzle 11 may be replaces to another nozzle 21 shown in FIG. 14A. A tip 21a of the nozzle 21 provides a pair of blades, 21b and 21c, facing to each other, and a portion 21d to suck the solder between the blades, 21b and 21c, into a port 21e. Each end of the blades, 21b or 21c, bends inward so as to narrow a gap therebetween. The nozzle 21 approaches the package as a side of the nozzle 21, where the gap between the blades, 21b and 21c, is wider, faces the package, the portions 21d catches the excess solder 16a and the solder may be sucked within the port 21e, as shown in FIG. 14B.

Thus, the foregoing is merely illustrative of the principles of the invention. Those skilled in the art will be able to devise numerous arrangements, which, although not explicitly shown or described herein, nevertheless embody those principles that are within the spirit and scope of the invention.

What is claimed is:

1. A method for assembling a semiconductor laser module that includes a carrier for mounting a semiconductor laser diode thereon, a thermo-electric cooler that fixed the carrier thereon to heat up or to cool down a temperature of the laser diode, and a package that installs the laser diode and the thermo-electric cooler therein, the method comprising steps of:
preparing a nozzle with a sucking port in a tip portion thereof;
positioning the carrier on the thermo-electric cooler with solder interposed therebetween;
melting the solder interposed between the carrier and the thermo-electric cooler; and
scanning the nozzle as the tip portion thereof being close to a gap between the carrier and the thermo-electric cooler so as to run the sucking port of the nozzle along the gap to suck excess solder oozed out the gap.

2. The method according to claim 1,
further comprising a step, after scanning the nozzle to such the excess solder, installing the thermo-electric cooler with the carrier fixed thereon within the package.

3. The method according to claim 1,
wherein the package has a box shape with four sides,
wherein the step for preparing the nozzle includes a step to prepare four nozzles each having the sucking port in the tip portion thereof and each nozzle corresponds to respective sides of the box shape package, and
wherein the step for scanning the nozzle includes a step for scanning each nozzle independently along the gap between the carrier and the thermo-electric cooler.
